(19) United States
(12) Patent Application Publication
(10) Pub. No.: US 2025/0357113 A1
(43) Pub. Date: Nov. 20, 2025

(54) SUBSTRATE PROCESSING METHOD AND SUBSTRATE PROCESSING APPARATUS

(71) Applicant: Tokyo Electron Limited, Tokyo (JP)

(72) Inventors: Daichi ITO, Yamanashi (JP); Jun OGAWA, Yamanashi (JP); Yamato TONEGAWA, Yamanashi (JP)

(21) Appl. No.: 19/174,162

(22) Filed: Apr. 9, 2025

(30) Foreign Application Priority Data
May 17, 2024 (JP) 2024-080867

(51) Int. Cl. H01L 21/02; H01J 37/32

(52) U.S. Cl. CPC H01L 21/0234; H01J 37/32449; H01L 21/0223; H01J 2237/338

(57) ABSTRACT

A technique capable of adjusting an etching selectivity ratio of an oxide film to a nitride film is provided. A substrate processing method includes: (a) preparing a substrate having a first region where a nitride film is formed and a second region where an oxide film is formed; (b) exposing the substrate to a plasma generated from a first processing gas containing hydrogen gas and oxygen gas; (c) supplying a second processing gas containing a fluorine-containing gas and a basic gas to the substrate; (d) performing the (b) and the (c) in this order a first number of times; and (e) thermally treating the substrate after the (d).

### CROSS-REFERENCE TO RELATED APPLICATION

The present application claims priority under 35 U.S.C. § 119 to Japanese Patent Application No. 2024-080867, filed May 17, 2024, the contents of which are incorporated herein by reference in their entireties.

### BACKGROUND OF THE INVENTION

### Field of the Invention

This disclosure relates to a substrate processing method and a substrate processing apparatus.

### Description of the Related Art

A disclosed technique supplies hydrogen gas and oxygen gas to an SiCN film formed on a surface of a substrate to oxidize a surface layer of the SiCN film and form an oxide film, and subsequently removes the oxide film by etching (see, for example, Japanese Patent Laid-Open Publication Application No. 2023-179001).

### SUMMARY OF THE INVENTION

A substrate processing method according to one embodiment of the present disclosure includes: (a) preparing a substrate having a first region where a nitride film is formed and a second region where an oxide film is formed; (b) exposing the substrate to a plasma generated from a first processing gas containing hydrogen gas and oxygen gas; (c) supplying a second processing gas containing a fluorine-containing gas and a basic gas to the substrate; (d) performing the (b) and the (c) in this order a first number of times; and (e) thermally treating the substrate after the (d).

### BRIEF DESCRIPTION OF THE DRAWINGS

FIG. 1 is a flowchart showing a substrate processing method according to an embodiment;

FIG. 2 is a vertical cross-sectional view showing a substrate processing apparatus according to an embodiment;

FIG. 3 is a horizontal cross-sectional view showing a substrate processing apparatus according to an embodiment;

FIG. 4 is a graph showing the relationship between a first number of times and an etching amount of an SiO₂ film;

FIG. 5 is a graph showing the relationship between a first number of times and an etching amount of an SiN film;

FIG. 6 is a graph showing the etching selectivity ratio of an SiO₂ film to an SiN film;

FIG. 7 is a view showing an example of a surface reaction of an SiO₂ film; and

FIG. 8 is a view showing another example of a surface reaction of an SiO₂ film.

### DETAILED DESCRIPTION OF THE DISCLOSURE

Hereinafter, non-limiting exemplary embodiments of the present disclosure will be described with reference to the attached drawings. In all the attached drawings, the same or corresponding members or parts will be denoted by the same or corresponding reference numerals, and duplicate descriptions will be omitted.

### [Substrate Processing Method]

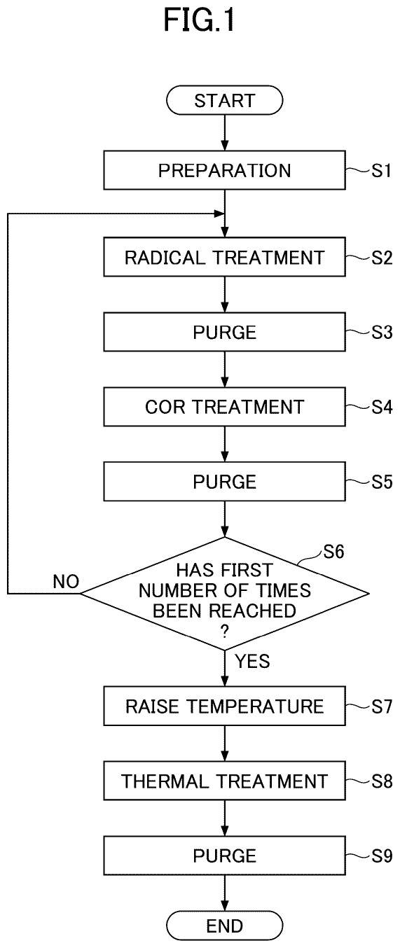

A substrate processing method according to an embodiment will be described with reference to FIG. 1. FIG. 1 is a flowchart showing the substrate processing method according to an embodiment. The substrate processing method according to the embodiment includes steps S1 to S9 shown in FIG. 1.

In step S1, a substrate is prepared. The substrate is, for example, a silicon wafer. The substrate has a first region where a nitride film is formed and a second region where an oxide film is formed. The nitride film is, for example, a film containing silicon (Si) and nitrogen (N). The film containing silicon and nitrogen is, for example, an SiN film or an SiCN film. The nitride film may further contain elements different from silicon and nitrogen. The different elements are, for example, oxygen (O), boron (B), or a combination thereof. The nitride film may be a film containing boron and nitrogen. The film containing boron and nitrogen is, for example, a BN film. The oxide film is, for example, a thermally oxidized film. The thermally oxidized film is, for example, an SiO₂ film.

In step S2, the substrate prepared in step S1 is subjected to a radical treatment. The radical treatment includes exposing the substrate to a plasma generated from a first processing gas containing hydrogen gas and oxygen gas. The plasma contains active species, such as oxygen radicals and the like.

In the radical treatment, the active species act on the surface layer of the nitride film, thereby oxidizing the surface layer of the nitride film and forming an oxide layer. In the radical treatment, it is possible to adjust the thickness of the oxide layer, by changing the flow rate ratio of the hydrogen gas and the oxygen gas contained in the first processing gas. For example, it is possible to increase the thickness of the oxide layer, by increasing the ratio of the flow rate of the oxygen gas to the flow rate of the hydrogen gas. The greater the thickness of the oxide layer, the greater the etching amount of the nitride film in step S8.

In the radical treatment, active species act on the surface layer of the oxide film, thereby modifying the surface layer of the oxide film and forming a modified layer. The modified layer reduces denaturation of the oxide film into a reaction product in a COR treatment in step S4. In the radical treatment, it is possible to adjust the film quality of the modified layer, by changing the flow rate ratio between the hydrogen gas and the oxygen gas contained in the first processing gas. The film quality may include film density. For example, it is possible to increase the film density of the modified layer, by increasing the ratio of the flow rate of the oxygen gas to the flow rate of the hydrogen gas. The higher the film density of the modified layer, the lower the etching amount of the oxide film in step S8.

In step S2, the flow rate ratio between the hydrogen gas and the oxygen gas contained in the first processing gas may be adjusted such that the etching selectivity ratio of the oxide film to the nitride film falls within a predetermined range. The first processing gas may further contain an inert gas, such as argon gas, nitrogen gas, and the like. Step S2 may include maintaining the temperature of the substrate at a first temperature. The first temperature is, for example, 80° C. or lower.

In step S3, purging is performed. The purging may include vacuuming the processing space in which the substrate is processed, thereby exhausting any gas remaining in the processing space. The purging may include exhausting any gas remaining in the processing space by supplying an inert gas, such as argon gas, nitrogen gas, or the like, into the processing space in which the substrate is processed.

In step S4, a Chemical Oxide Removal (COR) treatment is performed. The COR treatment includes supplying a second processing gas containing a fluorine-containing gas and a basic gas to the substrate without generating a plasma. In the COR treatment, the fluorine-containing gas and the basic gas react with the oxide layer and the oxide film to denature the oxide layer and the oxide film and produce ammonium silicofluoride [(NH₄)₂SiF₆], which is a reaction product. The fluorine-containing gas is, for example, hydrogen fluoride (HF) gas. The basic gas is, for example, ammonia (NH₃) gas. The second processing gas may further contain an inert gas, such as argon gas, nitrogen gas, and the like. Step S4 may include maintaining the temperature of the substrate at a second temperature. The second temperature is, for example, 50° C. or higher and 100° C. or lower. The second temperature may be the same as the first temperature. In this case, it is possible to continuously perform the radical treatment and the COR treatment without changing the temperature. Therefore, productivity is improved.

In step S5, purging is performed. The purging in step S5 may be the same as the purging in step S3.

In step S6, it is determined whether or not steps S2 to S5 have been performed in this order a first number of times. When the number of times these steps have been performed has not reached the first number of times (NO in step S6), steps S2 to S5 are performed again. When the number of times these steps have been performed has reached the first number of times (YES in step S6), the flow proceeds to step S7. Thus, the thickness of the oxide layer to be formed on the surface layer of the nitride film and the film quality of the modified layer to be formed on the surface layer of the oxide film are adjusted by repeating steps S2 to S5 in this order until the number of times these steps have been performed has reached the first number of times. As a result, the etching selectivity ratio of the oxide film to the nitride film can be adjusted to fall within a predetermined range. The first number of times may be once, or twice or more.

In step S7, the temperature of the substrate is raised from the second temperature to a third temperature. The third temperature is higher than the second temperature. The third temperature is, for example, 200° C. or higher.

In step S8, the substrate is thermally treated. The thermal treatment includes thermally treating the substrate in an atmosphere formed of an inert gas, such as argon gas, nitrogen gas, and the like, while maintaining the temperature of the substrate at the third temperature. In the thermal treatment, ammonium silicofluoride, which is the reaction product, is sublimated and removed from the substrate.

In step S9, purging is performed. The purging in step S9 may be the same as the purging in step S3. After the purging is performed in step S9, the flow is ended.

As described above, according to the substrate processing method of the embodiment, a substrate having a first region where a nitride film is formed and a second region where an oxide film is formed is prepared, then subjected to the radical treatment and the COR treatment in this order the first number of times, and then subjected to the thermal treatment. In this case, by changing the first number of times, it is possible to adjust the thickness of the oxide layer to be formed on the surface layer of the nitride film and the film quality of the modified layer to be formed on the surface layer of the oxide film. Therefore, the etching selectivity ratio of the oxide film to the nitride film can be adjusted.

It is also possible to adjust the etching selectivity ratio of the oxide film to the nitride film, by changing the COR treatment conditions, for example, temperature, flow rate ratio between the hydrogen fluoride gas and the ammonia gas, and pressure. However, the range in which the etching selectivity ratio can be adjusted through changing of the COR treatment conditions is small. In comparison to this, the substrate processing method of the embodiment ensures a large range in which the etching selectivity ratio of the oxide film to the nitride film can be adjusted.

In the embodiment, steps S2 to S9 may be performed in the same processing chamber. In this case, the radical treatment, the COR treatment, and the thermal treatment can be performed in one processing chamber. However, a part of steps S2 to S9 may be performed in a different processing chamber. For example, steps S8 and S9 may be performed in a different processing chamber from that in which steps S2 to S6 are performed. In this case, step S7 can be omitted.

The substrate processing method according to the embodiment may be performed in a processing chamber configured to contain a plurality of substrates in a shelf form. In this case, a plurality of substrates can be processed at a time. Therefore, productivity is improved.

### [Substrate Processing Apparatus]

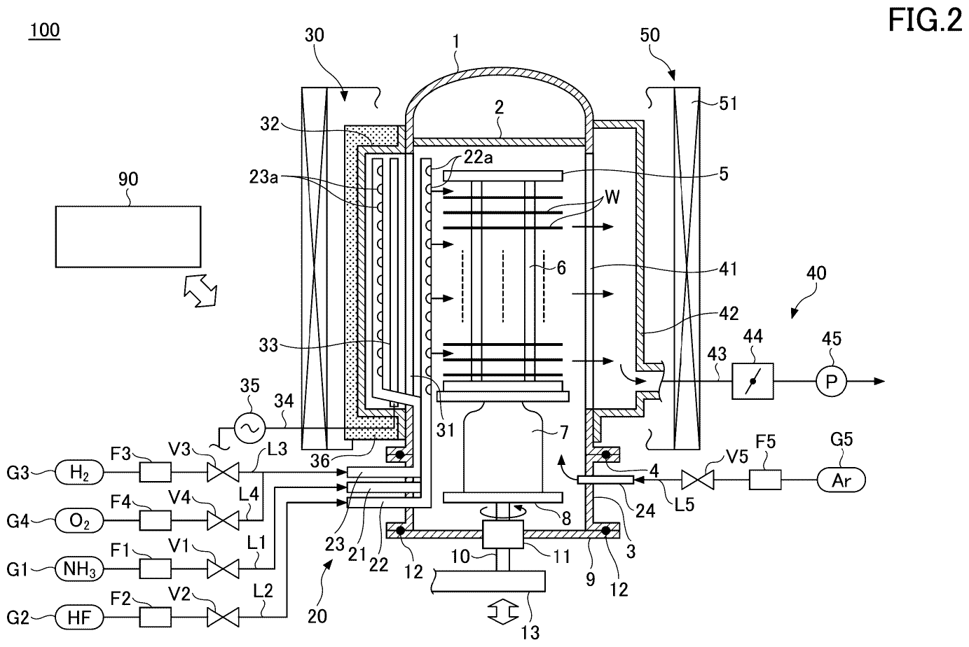

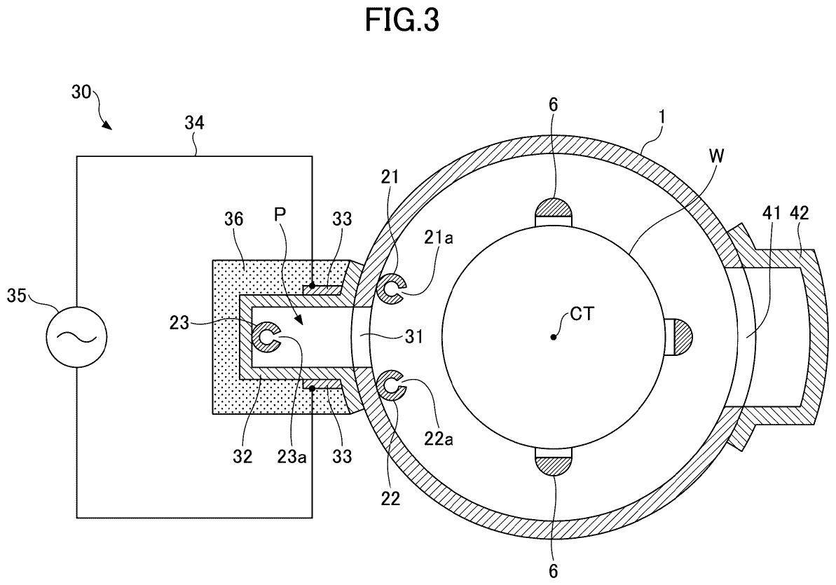

A substrate processing apparatus 100 according to an embodiment will be described with reference to FIGS. 2 and 3. FIG. 2 is a vertical cross-sectional view showing the substrate processing apparatus 100 according to the embodiment. FIG. 3 is a horizontal cross-sectional view showing the substrate processing apparatus 100 according to the embodiment. As shown in FIGS. 2 and 3, the substrate processing apparatus 100 includes a processing chamber 1, a gas supply part 20, a plasma generation part 30, a gas exhaust part 40, a heating part 50, and a controller 90.

The processing chamber 1 has a ceiled longitudinal cylindrical shape opened at the lower end. The processing chamber 1 is formed of, for example, quartz. A ceiling plate 2 is provided in the processing chamber 1 near the upper end of the processing chamber 1, and a region under the ceiling plate 2 is sealed. The ceiling plate 2 is formed of, for example, quartz. A cylindrical metallic manifold 3 is connected to the opening at the lower end of the processing chamber 1 via a seal member 4. The seal member 4 is, for example, an O-ring.

The manifold 3 supports the lower end of the processing chamber 1. A boat 5 is inserted into the processing chamber 1 from under the manifold 3. The boat 5 holds a plurality of (for example, 25 to 150) substrates W substantially horizontally at intervals provided along the vertical direction. The boat 5 is formed of, for example, quartz. The boat 5 has, for example, three supports 6, and the plurality of substrates W are supported in grooves formed in the supports 6.

The boat 5 is placed on a rotating table 8 via a thermal insulation cylinder 7. The thermal insulation cylinder 7 is formed of, for example, quartz. The thermal insulation cylinder 7 restricts heat dissipation from the opening at the lower end of the manifold 3. The rotating table 8 is supported on a rotation shaft 10. The opening at the lower end of the manifold 3 is opened and closed by a cover 9. The cover 9 is formed of, for example, a metal material, such as stainless steel and the like. The rotation shaft 10 penetrates the cover 9.

A magnetic fluid seal 11 is provided at the part penetrated by the rotation shaft 10. The magnetic fluid seal 11 airtightly seals and rotatably supports the rotation shaft 10. A seal member 12 is provided between the periphery of the cover 9 and the lower end of the manifold 3 for maintaining airtightness in the processing chamber 1. The seal member 12 is, for example, an O-ring.

The rotation shaft 10 is attached to an end of an arm 13 supported by a lifting mechanism, such as a boat elevator and the like. When the arm 13 is moved upward or downward, the boat 5, the thermal insulation cylinder 7, the rotating table 8, and the cover 9 are moved upward or downward integrally with the rotation shaft 10, to be inserted into and removed from the processing chamber 1.

The gas supply part 20 supplies various processing gases into the processing chamber 1. The gas supply part 20 includes, for example, a gas nozzle 21, a gas nozzle 22, a gas nozzle 23, and a gas nozzle 24. The gas nozzle 21, the gas nozzle 22, the gas nozzle 23, and the gas nozzle 24 are formed of, for example, quartz. The gas supply part 20 may further include another gas nozzle.

The gas nozzle 21 has an L-letter shape that penetrates the side wall of the manifold 3 inward, and is bent upward and extends vertically. A vertical part of the gas nozzle 21 is provided in the processing chamber 1. A plurality of gas holes 21a are provided in the vertical part of the gas nozzle 21. The plurality of gas holes 21a are provided at predetermined intervals along the extending direction of the gas nozzle 21. Each gas hole 21a is oriented to, for example, the center CT of the processing chamber 1.

A supply path L1 is connected to the gas nozzle 21. The supply path L1 is provided with a supply source G1 of ammonia gas, a mass flow controller F1, and an opening/closing valve V1 in an order from the upstream side to the downstream side in the gas flow direction. Ammonia gas is an example of the basic gas. The supply timing of the ammonia gas in the supply source G1 is controlled by the opening/closing valve V1, and the flow rate thereof is adjusted to a predetermined flow rate by the mass flow controller F1. The ammonia gas flows into the gas nozzle 21 through the supply path L1 and is discharged horizontally from the plurality of gas holes 21a toward the center CT of the processing chamber 1.

The gas nozzle 22 has an L-letter shape that penetrates the side wall of the manifold 3 inward, and is bent upward and extends vertically. A vertical part of the gas nozzle 22 is provided in the processing chamber 1. A plurality of gas holes 22a are provided in the vertical part of the gas nozzle 22. The plurality of gas holes 22a are provided at predetermined intervals along the extending direction of the gas nozzle 22. Each gas hole 22a is oriented to, for example, the center CT of the processing chamber 1.

A supply path L2 is connected to the gas nozzle 22. The supply path L2 is provided with a supply source G2 of hydrogen fluoride gas, a mass flow controller F2, and an opening/closing valve V2 in an order from the upstream side to the downstream side in the gas flow direction. The hydrogen fluoride gas is an example of the fluorine-containing gas. The supply timing of the hydrogen fluoride gas in the supply source G2 is controlled by the opening/closing valve V2, and the flow rate thereof is adjusted to a predetermined flow rate by the mass flow controller F2. The hydrogen fluoride gas flows into the gas nozzle 22 through the supply path L2, and is discharged horizontally from the plurality of gas holes 22a toward the center CT of the processing chamber 1.

The gas nozzle 23 has an L-letter that penetrates the side wall of the manifold 3 inward, and is bent upward and extends vertically. A vertical part of the gas nozzle 23 is provided in a plasma generation space P. A plurality of gas holes 23a are provided in the vertical part of the gas nozzle 23. The plurality of gas holes 23a are provided at predetermined intervals along the extending direction of the gas nozzle 23. Each of the gas holes 23a is oriented to, for example, the center CT of the processing chamber 1.

A supply path L3 is connected to the gas nozzle 23. The supply path L3 is provided with a supply source G3 of hydrogen gas, a mass flow controller F3, and an opening/closing valve V3 in an order from the upstream side to the downstream side in the gas flow direction. The supply timing of the hydrogen gas in the supply source G3 is controlled by the opening/closing valve V3, and the flow rate thereof is adjusted to a predetermined flow rate by the mass flow controller F3. The hydrogen gas flows into the gas nozzle 23 through the supply path L3, and is discharged horizontally from the plurality of gas holes 23a toward the center CT of the processing chamber 1.

A supply path L4 is connected to the gas nozzle 23. The supply path L4 may be connected to the supply path L3 at the downstream of the opening/closing valve V3. The supply path L4 is provided with a supply source G4 of oxygen gas, a mass flow controller F4, and an opening/closing valve V4 in an order from the upstream side to the downstream side in the gas flow direction. The supply timing of the oxygen gas in the supply source G4 is controlled by the opening/closing valve V4, and the flow rate thereof is adjusted to a predetermined flow rate by the mass flow controller F4. The oxygen gas flows into the gas nozzle 23 through the supply path L4, and is discharged horizontally from the plurality of gas holes 23a toward the center CT of the processing chamber 1.

The gas nozzle 24 has a straight tube shape that penetrates the side wall of the manifold 3 and extends horizontally. An end part of the gas nozzle 24 is provided in the processing chamber 1. The end part of the gas nozzle 24 is opened.

A supply path L5 is connected to the gas nozzle 24. The supply path L5 is provided with a supply source G5 of argon gas, a mass flow controller F5, and an opening/closing valve V5 in an order from the upstream side to the downstream side in the gas flow direction. Argon 1 gas is an example of the inert gas. The supply timing of the argon gas in the supply source G5 is controlled by the opening/closing valve V5, and the flow rate thereof is adjusted to a predetermined flow rate by the mass flow controller F5. The argon gas flows into the gas nozzle 24 through the supply path L5 and is discharged into the processing chamber 1 through the opening at the tip.

The plasma generation part 30 is provided on a part of the side wall of the processing chamber 1. The plasma generation part 30 generates a plasma from the hydrogen gas and the oxygen gas supplied from the gas nozzle 23. The plasma generation part 30 includes a plasma partition wall 32, a pair of plasma electrodes 33, a power supply line 34, an RF power source 35, and an insulating protection cover 36.

The plasma partition wall 32 is airtightly welded to the outer wall of the processing chamber 1. The plasma partition wall 32 is formed of, for example, quartz. The plasma partition wall 32 has a box cross-sectional shape and covers an opening 31 formed in the side wall of the processing chamber 1. The opening 31 is formed in an elongated shape extending in the vertical direction so as to be able to cover all the substrates W supported by the boat 5 in the vertical direction. The plasma partition wall 32 defines the plasma generation space P, which is an inner space communicating with the interior of the processing chamber 1.

The pair of plasma electrodes 33, each of which has an elongated shape, are situated on the outer surfaces of walls of the plasma partition wall 32 on facing sides, such that the air of plasma electrodes 33 extend along the vertical direction and face each other. The power supply line 34 is connected to the lower end of each plasma electrode 33.

The power supply line 34 electrically connects each plasma electrode 33 and the RF power source 35. For example, one end of the power supply line 34 is connected to the lower end of each plasma electrode 33 on the side of a shorter side of the plasma electrode 33, and the other end of the power supply line 34 is connected to the RF power source 35.

The RF power source 35 is electrically connected to the lower end of each plasma electrode 33 through the power supply line 34. The RF power source 35 supplies an RF power, for example, 13.56 MHz to the pair of plasma electrodes 33. Thus, an RF power is applied to the plasma generation space P defined by the plasma partition wall 32.

The insulating protection cover 36 is mounted on the outer side of the plasma partition wall 32 so as to cover the plasma partition wall 32. A refrigerant path (not shown) is provided inside the insulating protection cover 36. The plasma electrodes 33 are cooled by flowing a cooled refrigerant, such as nitrogen gas or the like, through the refrigerant path. A shield (not shown) may be provided between the plasma electrodes 33 and the insulating protection cover 36 so as to cover the plasma electrodes 33. The shield is formed of, for example, a good conductor, such as a metal or the like, and is electrically grounded.

The gas exhaust part 40 has a gas exhaust port 41. The gas exhaust port 41 is provided in a side wall part of the processing chamber 1. The gas exhaust port 41 is provided at a position facing the opening 31. The gas exhaust port 41 is formed in an elongated shape extending vertically so as to match the boat 5. A cover member 42 formed in a U-letter cross-sectional shape so as to cover the gas exhaust port 41 is attached to a part of the processing chamber 1 corresponding to the gas exhaust port 41. The cover member 42 extends upward along the side wall of the processing chamber 1. A gas exhaust pipe 43 is connected to a lower part of the cover member 42. The gas exhaust pipe 43 is provided with a pressure regulating valve 44 and a vacuum pump 45 in an order from the upstream to the downstream in the gas flow direction. The pressure regulating valve 44 regulates the pressure in the processing chamber 1. The vacuum pump 45 exhausts gases from the processing chamber 1.

The heating part 50 includes a heater 51. The heater 51 has a cylindrical shape surrounding the processing chamber 1 on the outer side of the processing chamber 1 in the radial direction. The heater 51 heats each substrate W contained in the processing chamber 1 by heating the entire lateral periphery of the processing chamber 1.

The controller 90 is an electronic circuit, such as a Central Processing Unit (CPU), a Field Programmable Gate Array (FPGA), an Application Specific Integrated Circuit (ASIC), and the like. The controller 90 performs various control operations described in this application by executing instruction codes stored in a memory or by being designed as a circuit for a special application.

### [Operation of Substrate Processing Apparatus]

The operation of the substrate processing apparatus 100 when the substrate processing method according to the embodiment is performed in the substrate processing apparatus 100 will be described below.

First, the controller 90 ascends the arm 13 to load the boat 5 holding a plurality of substrates W into the processing chamber 1, and airtightly closes and seals the opening at the lower end of the processing chamber 1 with the cover 9. Each substrate W has a first region where a nitride film is formed and a second region where an oxide film is formed.

Next, the controller 90 controls each part of the substrate processing apparatus 100 so as to perform steps S2 to S9 of the substrate processing method described above. The controller 90 adjusts the thickness of the oxide layer to be formed on the surface layer of the nitride film and the film quality of the modified layer to be formed on the surface layer of the oxide film by changing the first number of times in step S6. Thus, the etching selectivity ratio of the oxide film to the nitride film can be adjusted.

Next, the controller 90 raises the pressure in the processing chamber 1 to the open-air pressure, lowers the temperature in the processing chamber 1 to an unloading temperature, and then descends the arm 13 to unload the boat 5 from the processing chamber 1. Thus, the processing of the plurality of substrates W is completed.

### [Experiment]

First, substrates having SiO₂ films on their surfaces and substrates having SiN films on their surfaces were prepared. Next, the prepared substrates were accommodated in the processing chamber 1 of the substrate processing apparatus 100, and subjected to steps S2 to S9 of the substrate processing method described above in the processing chamber 1. In step S6, the first number of times was changed. The first number of times was 1, 3, 5, and 10. In step S2, the flow rate of each gas contained in the first processing gas was changed. The flow rate of each gas was as follows.
Condition A1: H₂/O₂/N₂=0 sccm/0 sccm/2,450 Sccm
Condition A2: H₂/O₂/N₂=1,400 sccm/500 sccm/550 sccm
Condition A3: H₂/O₂/N₂=2,000 sccm/8,000 sccm/550 sccm

The conditions of the radical treatment (step S2), the COR treatment (step S4), and the thermal treatment (step S8) were as follows.

### (Radical Treatment)

Substrate temperature: 65° C.
Time: 10 minutes
RF power: ON

### (COR Treatment)

Substrate temperature: 65° C.
Time: 1 minute
RF Power: OFF
Second processing gas: hydrogen fluoride gas/ammonia gas/nitrogen gas=300 sccm/300 sccm/550 Sccm

### (Thermal Treatment)

Substrate temperature: 300° C.
Treatment atmosphere: nitrogen gas

Next, the etching amount of the SiO₂ film and the etching amount of the SiN film were measured.

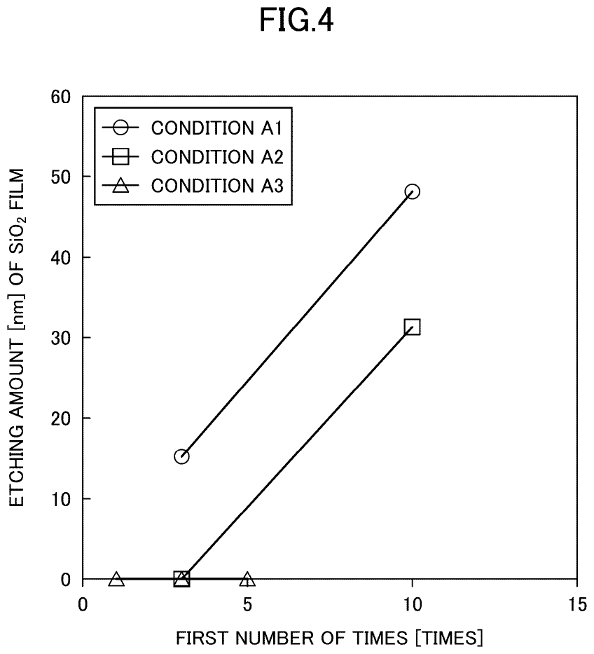

FIG. 4 is a graph showing the relationship between the first number of times and the etching amount of the SiO₂ films. In FIG. 4, the horizontal axis indicates the first number of times [times], and the vertical axis indicates the etching amount [mm] of the SiO₂ films. In FIG. 4, the circles indicate the results of the radical treatment under the condition A1, the squares indicate the results of the radical treatment under the condition A2, and the triangles indicate the results of the radical treatment under the condition A3.

As shown in FIG. 4, the magnitude relationship between the etching amounts of the SiO₂ films when compared based on the same first number of times is condition A1>condition A2>condition A3. This result indicates that the radical treatment of the SiO₂ film reduced the etching amount of the SiO₂ film. The result also indicates that the higher the ratio of the flow rate of the oxygen gas to the flow rate of the hydrogen gas contained in the first processing gas, the lower the etching amount of the SiO₂ film.

As shown in FIG. 4, under the condition A2, the greater the first number of times, the greater the etching amount of the SiO₂ film. This result indicates that it was possible to control the etching amount of the SiO₂ film by changing the first number of times. Specifically, increasing the first number of times increases the etching amount of the SiO₂ film.

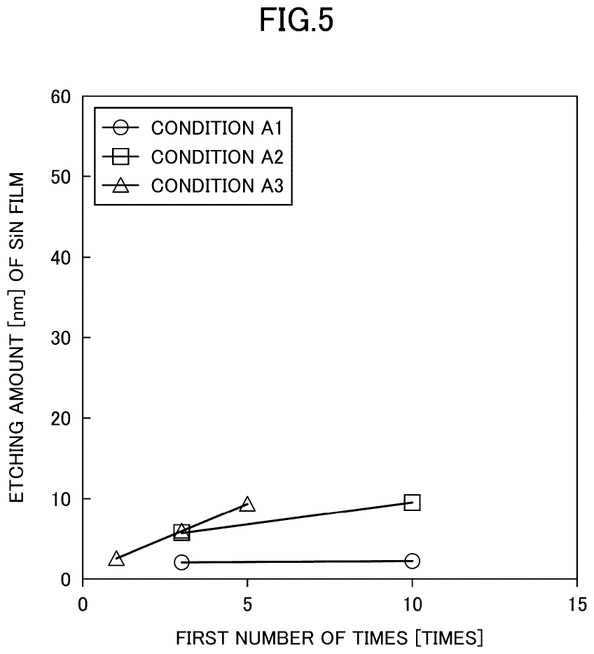

FIG. 5 is a graph showing the relationship between the first number of times and the etching amount of the SiN films. In FIG. 5, the horizontal axis indicates the first number of times [times], and the vertical axis indicates the etching amount of the SiN films [nm]. In FIG. 5, the circles indicate the results of the radical treatment under the condition A1, the squares indicate the results of the radical treatment under the condition A2, and the triangles indicate the results of the radical treatment under the condition A3.

As shown in FIG. 5, the magnitude relationship between the etching amounts of the SiN films when compared based on the same first number of times is condition A1<condition A2<condition A3. This result indicates that the radical treatment of the SiN film increased the etching amount of the SiN film. The result also indicates that the higher the ratio of the flow rate of the oxygen gas to the flow rate of the hydrogen gas contained in the first processing gas, the higher the etching amount of the SiN film.

As shown in FIG. 5, under the conditions A2 and A3, the greater the first number of times, the greater the etching amount of the SiN film. This result indicates that it was possible to control the etching amount of the SiN film by changing the first number of times. Specifically, increasing the first number of times increases the etching amount of the SiN film.

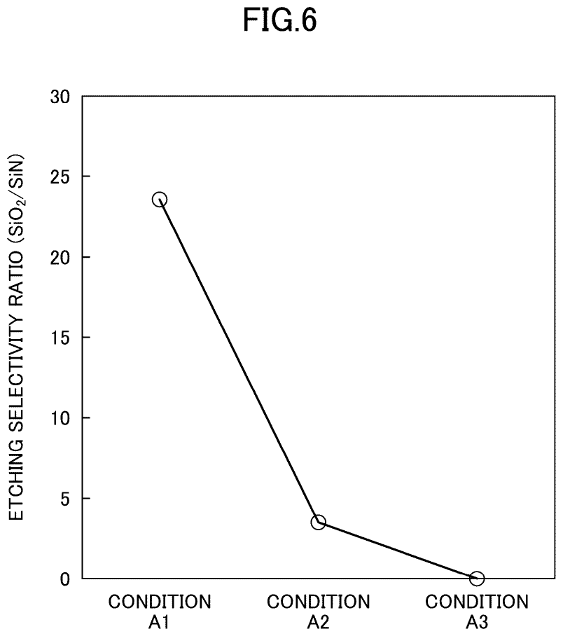

FIG. 6 shows the etching selectivity ratio of the SiO₂ film to the SiN film. In FIG. 6, the horizontal axis indicates the condition, and the vertical axis indicates the etching selectivity ratio (SiO₂/SiN selectivity ratio) of the silicon oxide film to the silicon nitride film when the first number of time is 10.

As shown in FIG. 6, the etching selectivity ratio of the silicon oxide film to the silicon nitride film was 23.5 under the condition A1, 3.4 under the condition A2, and 0 under the condition A3. This result indicates that it was possible to adjust the etching selectivity ratio of the oxide film to the nitride film by changing the flow rate ratio between the hydrogen gas and the oxygen gas contained in the first processing gas.

### [Surface Reaction of SiO₂ Film]

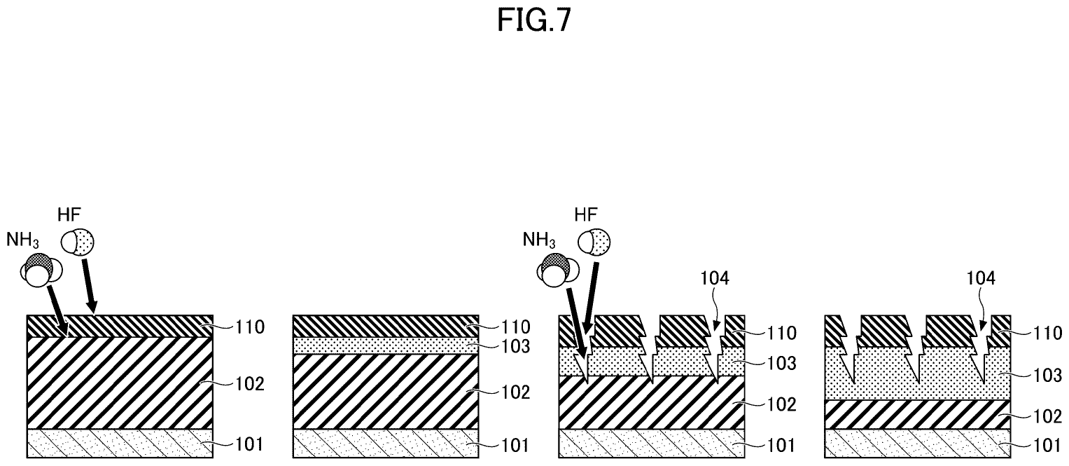

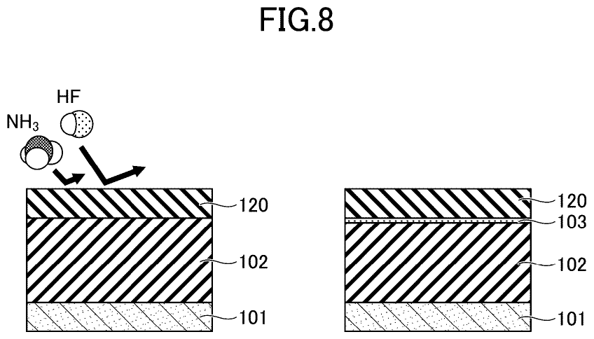

The surface reaction of an SiO₂ film will be described with reference to FIGS. 7 and 8. Hereinafter, the reaction mechanism that is considered to occur on a surface of an SiO₂ film when a substrate having the SiO₂ film on a surface was repeatedly subjected to the radical treatment and the COR treatment in this order will be described.

FIG. 7 is a view showing an example of the surface reaction of an SiO₂ film. FIG. 7 is a view showing the surface reaction of an SiO₂ film when a substrate having the SiO₂ film on a surface was repeatedly subjected to the radical treatment and the COR treatment in this order. FIG. 7 shows a case where the radical treatment was performed under the condition A2 of the above experiment.

As shown in the leftmost view of FIG. 7, when the substrate 101 having the SiO₂ film 102 on a surface is subjected to the radical treatment under the condition A2, a modified layer 110 is formed on the surface layer of the SiO₂ film 102. Thus, the surface of the SiO₂ film 102 is covered with the modified layer 110. When the COR treatment is performed with the surface of the SiO₂ film 102 covered with the modified layer 110, the modified layer 110 inhibits hydrogen fluoride (HF) and ammonia (NH₃) contained in the second processing gas from reaching the SiO₂ film 102. Thus, only part of fluorine (HF) and ammonia (NH₃) reaches the SiO₂ film 102. Therefore, it is difficult for the SiO₂ film 102 to denature into an ammonium silicofluoride layer 103. For example, as shown in the second view from the left in FIG. 7, a part of the surface of the SiO₂ film 102 denatures into the ammonium silicofluoride layer 103.

As shown in the second view from the right in FIG. 7, when the substrate 101 is repeatedly subjected to the radical treatment and the COR treatment in this order, cracks 104 are generated in the modified layer 110 at some point in time. As a result, hydrogen fluoride (HF) and ammonia (NH₃) reach the SiO₂ film 102 through the cracks 104, contributing to denaturation of the SiO₂ film 102 into the ammonium silicofluoride layer 103. Therefore, as shown in the rightmost view in FIG. 7, the thickness of the ammonium silicofluoride layer 103 increases. As a result, when the substrate 101 is thermally treated, the ammonium silicofluoride layer 103 is etched.

When the radical treatment is performed under the condition A2, it is difficult for cracks 104 to occur in the modified layer 110 until the number of times to repeat the radical treatment and the COR treatment (the first number of times) is small. Therefore, it is considered that the etching of the SiO₂ film 102 hardly proceeds until the first number of times is small (3 or less in the example of FIG. 4), and that the etching of the SiO₂ film 102 proceeds when the first number of times has exceeded a certain number of times (3 in the example of FIG. 4).

FIG. 8 is a view showing another example of the surface reaction of an SiO₂ film. FIG. 8 is a view showing the surface reaction of an SiO₂ film when a substrate having the SiO₂ film on a surface was repeatedly subjected to the radical treatment and the COR treatment in this order. FIG. 8 shows a case where the radical treatment was performed under the condition A3 of the above experiment.

As shown in the left view in FIG. 8, when a substrate 101 having an SiO₂ film 102 on a surface is subjected to the radical treatment under the condition A3, a modified layer 120 is formed on the surface layer of the SiO₂ film 102. Thus, the surface of the SiO₂ film 102 is covered with the modified layer 120. Under the condition A3, the ratio of the flow rate of the oxygen gas to the flow rate of the hydrogen gas is higher than that under the condition A2. Therefore, the modified layer 120 is considered to have a higher film density than that of the modified layer 110. When the COR treatment is performed with the SiO₂ film 102 covered with the modified layer 120, the modified layer 120 inhibits hydrogen fluoride (HF) and ammonia (NH₃) contained in the second processing gas from reaching the SiO₂ film 102. When the surface of the SiO₂ film 102 is covered with the modified layer 120, it is more difficult for fluorine (HF) and ammonia (NH₃) to reach the SiO₂ film 102 than when the surface of the SiO₂ film is covered with the modified layer 110. Therefore, when the surface of the SiO₂ film 102 is covered with the modified layer 120, it is difficult for the SiO₂ film 102 to denature into the ammonium silicofluoride layer 103 than when the surface of the SiO₂ film is covered with the modified layer 110. For example, as shown in the right view of FIG. 8, the SiO₂ film 102 hardly denatures into the ammonium silicofluoride layer 103. As a result, even when the substrate 101 is thermally treated, the SiO₂ film 102 is hardly etched.

The embodiments disclosed herein should be considered exemplary and non-limiting in all respects. Various omissions, substitutions, and modifications are applicable to the above embodiments without departing from the scope and spirit of the appended claims.

In the above embodiments, a case where the substrate processing apparatus is a batch-type apparatus for processing a plurality of substrates at a time has been described. However, the present disclosure is not limited to this. For example, the substrate processing apparatus may be a single-wafer-type apparatus for processing one substrate at a time.

According to the present disclosure, it is possible to adjust the etching selectivity ratio of an oxide film to a nitride film.

What is claimed is:

1. A substrate processing method, comprising:
(a) preparing a substrate having a first region where a nitride film is formed and a second region where an oxide film is formed;
(b) exposing the substrate to a plasma generated from a first processing gas containing hydrogen gas and oxygen gas;
(c) supplying a second processing gas containing a fluorine-containing gas and a basic gas to the substrate;
(d) performing the (b) and the (c) in this order a first number of times; and
(e) thermally treating the substrate after the (d).

2. The substrate processing method according to claim 1,
wherein the (b) includes oxidizing a surface layer of the nitride film to form an oxide layer.

3. The substrate processing method according to claim 2,
wherein the (c) includes denaturing the oxide layer into a reaction product, and
the (e) includes sublimating and removing the reaction product.

4. The substrate processing method according to claim 1,
wherein the (b) includes modifying the oxide film to form a modified layer.

5. The substrate processing method according to claim 1,
wherein the (b) includes adjusting a flow rate ratio between the hydrogen gas and the oxygen gas such that an etching selectivity ratio of the oxide film to the nitride film falls within a predetermined range.

6. The substrate processing method according to claim 1,
wherein the (d) includes adjusting the first number of times such that an etching selectivity ratio of the oxide film to the nitride film falls within a predetermined range.

7. The substrate processing method according to claim 1,
wherein the (b) includes maintaining a temperature of the substrate at a first temperature,
the (c) includes maintaining the temperature of the substrate at a second temperature, and
the second temperature is the same as the first temperature.

8. The substrate processing method according to claim 7,
wherein the (e) includes maintaining the temperature of the substrate at a third temperature, and
the third temperature is higher than the second temperature.

9. The substrate processing method according to claim 1,
wherein the (c) is performed in a same processing chamber as that in which the (b) is performed.

10. The substrate processing method according to claim 1,
wherein the nitride film is an SiN film, an SiCN film, or a BN film.

11. The substrate processing method according to claim 1,
wherein the oxide film is a thermally oxidized film.

12. The substrate processing method according to claim 11,
wherein the thermally oxidized film is an SiO₂ film.

13. A substrate processing apparatus, comprising:
a processing chamber;
a gas supply part configured to supply a processing gas into the processing chamber; and
a controller,
wherein the controller is configured to perform:
(a) preparing a substrate having a first region where a nitride film is formed and a second region where an oxide film is formed;
(b) exposing the substrate to a plasma generated from a first processing gas containing hydrogen gas and oxygen gas;
(c) supplying a second processing gas containing a fluorine-containing gas and a basic gas to the substrate;
(d) performing the (b) and the (c) in this order a first number of times; and
(e) thermally treating the substrate after the (d).
